(19) United States
(12) Patent Application Publication
(10) Pub. No.: US 2008/0188089 A1
(43) Pub. Date: Aug. 7, 2008

(54) METHOD FOR REDUCING TOP NOTCHING EFFECTS IN PRE-DOPED GATE STRUCTURES

(75) Inventors: Anthony I. Chou, Beacon, NY (US); Sadanand V. Deshpande, Lagrangeville, NY (US); Renee T. Mo, Briarcliff Manor, NY (US); Shreesh Narasimha, Beacon, NY (US); Katsunori Onishi, Fishkill, NY (US); Dominic Schepis, Wappingers Falls, NY (US)

Correspondence Address: CANTOR COLBURN LLP - IBM FISHKILL, 20 Church Street, 22nd Floor, Hartford, CT, 06103, US

(73) Assignee: International Business Machines Corporation, Armonk, NY (US)

(21) Appl. No.: 11/671,668

(22) Filed: Feb. 6, 2007

(51) Int. Cl. H01L 21/31

(52) U.S. Cl. 438/770

(57) ABSTRACT

A method for reducing top notching effects in pre-doped gate structures includes subjecting an etched, pre-doped gate stack structure to a re-oxidation process, the re-oxidation process comprising a radical assisted re-oxidation process so as to result in the formation of an oxide layer over vertical sidewall and horizontal top surfaces of the etched gate stack structure. The resulting oxide layer has a substantially uniform thickness independent of grain boundary orientations of the gate stack structure and independent of the concentration and location of dopant material present therein.

### BACKGROUND

The present invention relates generally to semiconductor device processing techniques and, more particularly, to a method for reducing top notching effects in pre-doped gate structures.

In today's most advanced semiconductor devices, the gate implant material is also received by the source/drain regions of a field effect transistor (FET). Typically, the maximum amount of dopant that the gate can receive is limited by the amount that the source/drain regions can tolerate. For example, current state-of-the-art NFETs use phosphorus (P) at the dopant for the source/drain regions. If too much phosphorus is implanted into the source/drain regions, then lateral phosphorus diffusion may be excessive, thereby causing degraded short channel effects. On the other hand, implanting high doses of phosphorus (e.g., on the order of about 5×10¹⁵ atoms/cm² or greater) into the gate actually reduces the gate depletion effect and improves the device characteristics.

In certain existing processes, wider source/drain spacers may be used to accommodate a higher dose of phosphorus into the source/drain regions. However, this causes the series resistance of the transistor to significantly increase. Alternatively, if (heavier) arsenic (As) is used for the source/drain doping, achieving comparable gate activation with respect to phosphorus is difficult for the same thermal cycle. In order to achieve maximum flexibility in achieving the least poly depletion and best short channel effect control, independent doping of the source/drain regions and the gate regions is therefore desirable.

One existing approach for independent doping of the gate and the source/drain regions includes the use of a so-called gate “pre-doping” scheme. In one implementation of pre-doping of N-type devices, a polysilicon layer is deposited onto a surface of a gate dielectric (e.g., an oxide) that is formed atop a semiconductor substrate. Then, a lithographic step to block (mask) the PFET regions of the substrate, after which dopant ions are implanted into the polysilicon material of the exposed NFET regions of the device. Generally, the relatively high concentration of NFET gate dopant material is localized to the upper third of the poly silicon layer to prevent subsequent diffusion down into the gate dielectric. The mask (resist) is then stripped, which may or may not be followed by a cleaning step and second lithography step to pre-dope the PFET regions of the polysilicon layer. In either case, a gate etch step is then used define the gate stacks of both the NFET and PFET devices.

Prior to source/drain implantation and after a cleaning process, the device then subjected to a gate re-oxidation process in which an oxide liner is formed over the vertical sidewall and horizontal top surfaces of the gate stacks. Conventionally, gate re-oxidation is performed through a furnace-based process in an oxidizing ambient such as O₂ or air at a temperature of about 800° C. or more for a time period of about 5 minutes or less. However, with such a process, the rate at which oxide is formed on the polysilicon gate structures is both grain boundary dependent as well as dopant dependent. In particular, the rate of furnace-based oxidation is increased at regions of high-dopant concentrations, thus resulting in “top-notching” of the polysilicon gate structures.

Unfortunately, with gate devices continuing to scale down such that polysilicon gate heights are formed at 50 nm or less, the benefits of gate pre-doping are being negated due to the uneven growth of oxide in the highly pre-doped regions. That is, the effects of top notching (e.g., loss of pre-dopant material) are exacerbated as gate heights continue to shrink in size. Accordingly, it would be desirable to be able to implement gate re-oxidation in a manner that is relatively independent of grain boundary conditions and/or gate dopant concentrations.

### SUMMARY

The foregoing discussed drawbacks and deficiencies of the prior art are overcome or alleviated by a method for reducing top notching effects in pre-doped gate structures. In an exemplary embodiment, the method includes subjecting an etched, pre-doped gate stack structure to a re-oxidation process, the re-oxidation process comprising a radical assisted re-oxidation process so as to result in the formation of an oxide layer over vertical sidewall and horizontal top surfaces of the etched gate stack structure; wherein the oxide layer has a substantially uniform thickness independent of grain boundary orientations of the gate stack structure and independent of the concentration and location of dopant material present therein.

In another embodiment, a method of forming a gate stack structure for a semiconductor device includes forming a gate dielectric layer over a semiconductor substrate; forming a gate conductor layer over the gate dielectric layer; subjecting unmasked regions of the gate conductor layer to an ion implantation of dopant material; patterning and etching the gate conductor layer and gate dielectric layer so as to form a pre-doped gate stack structure; and subjecting the gate stack structure to a re-oxidation process, the re-oxidation process comprising a radical assisted re-oxidation process so as to result in the formation of an oxide layer over vertical sidewall and horizontal top surfaces of the etched gate stack structure. The oxide layer has a substantially uniform thickness independent of grain boundary orientations of the gate stack structure and independent of the concentration and location of dopant material present therein.

### BRIEF DESCRIPTION OF THE DRAWINGS

Referring to the exemplary drawings wherein like elements are numbered alike in the several Figures:

FIGS. 1(a) through 1(f) are a series of schematic cross sectional views illustrating a conventional, furnace-based method of etched gate structure re-oxidation used in the formation of FET devices;

FIG. 2 is a process flow diagram illustrating a method for reducing top notching effects in pre-doped gate structures, in accordance with an embodiment of the invention;

FIG. 3 is a transmission electron micrograph (TEM) photograph illustrating the top notching effect resulting from furnace-based gate re-oxidation; and

FIG. 4 is a transmission electron micrograph (TEM) photograph illustrating the improved results using the method described by FIG. 2.

### DETAILED DESCRIPTION

Disclosed herein is a method and structure for method for reducing top notching effects in pre-doped gate structures. Briefly stated, a conventional furnace-based re-oxidation of an etched, pre-doped polysilicon gate structure (e.g., N-type gate with high concentration phosphorus dopant) is replaced with a low-temperature, radical assisted oxidation process that is grain boundary independent so as to reduce dopant loss and re-oxidize the gate surfaces at a more constant rate.

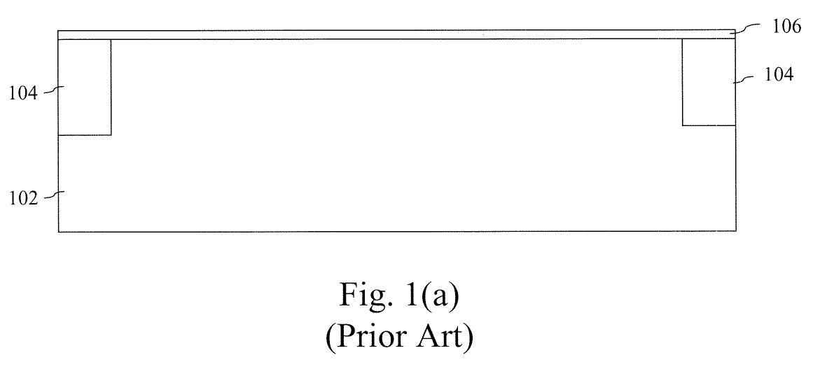

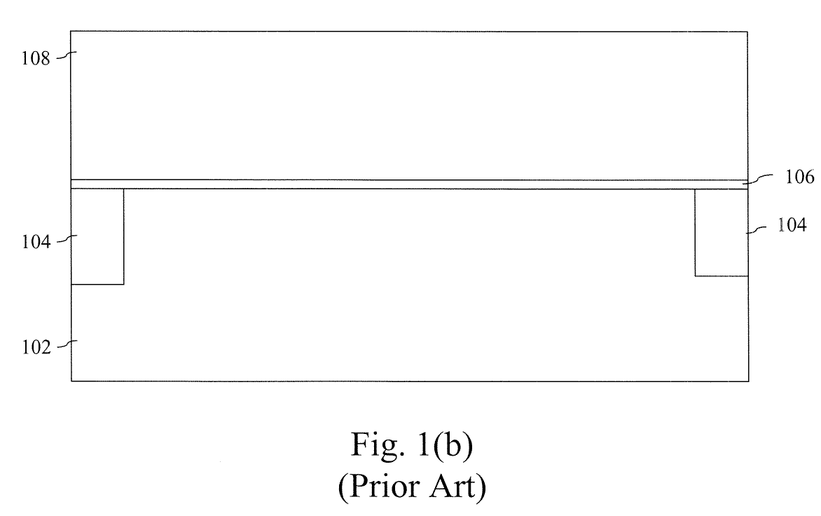

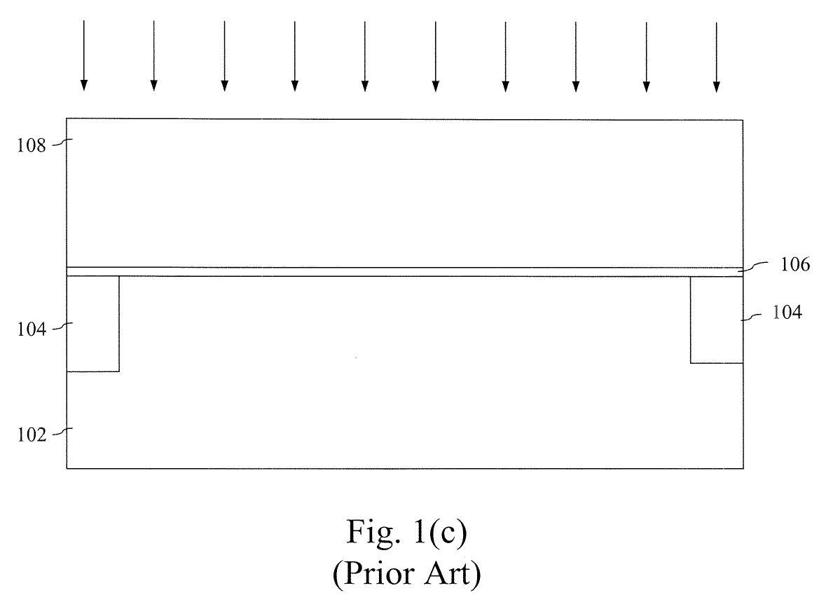

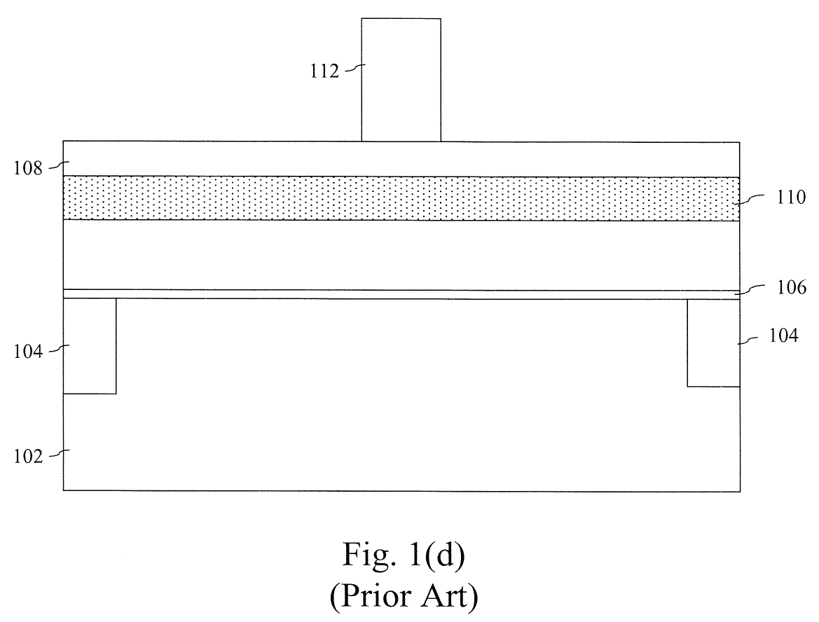

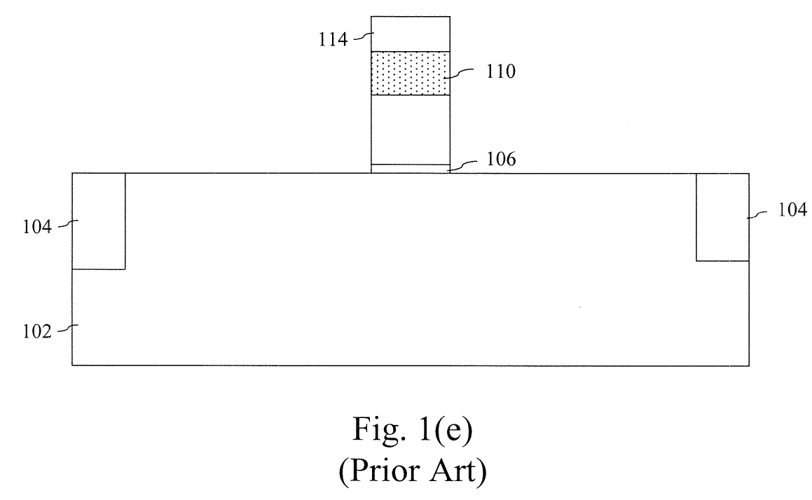

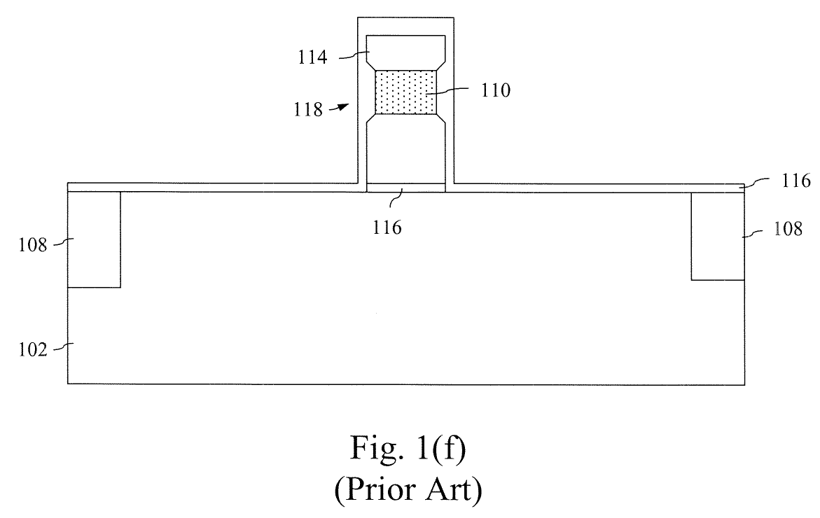

Referring initially to FIGS. 1(a) through 1(f), there is shown a series of schematic cross sectional view illustrating a conventional, furnace-based method of etched gate structure re-oxidation used in the formation of FED devices. In FIG. 1(a), a semiconductor substrate 102 (e.g., silicon, silicon germanium, silicon-on-insulator (SOI), silicon carbide, silicon germanium carbide, or other layers structures, etc.) has a plurality of shallow trench isolation (STI) regions 104 formed therein for isolating transistor devices from one another. A gate dielectric (insulating layer 106 is then formed over the top of the substrate 102 and STI regions 104 utilizing a conventional process such as chemical vapor deposition (CVD), plasma-assisted CVD (PECVD), evaporation, sputtering, atomic layer chemical vapor deposition (ALCVD), molecular beam epitaxy (MBE) and chemical solution deposition. Alternatively, the gate dielectric layer 106 may be formed by a thermal oxidation, nitridation or oxynitridation process.

Exemplary gate dielectric materials include, but are not limited to oxides, nitrides, oxynitrides, mixtures and multilayers thereof. After formation of the gate dielectric layer 106, FIG. 1(b) illustrates the formation of a gate conductor layer 108 (e.g., polysilicon) over the gate dielectric layer 106. As indicated above, it is desirable to pre-dope the gate conductor material prior to gate stack formation and source/drain implantation due to the benefits of having the gate more highly doped (particularly for NFET devices) with respect to the source/drain regions. Accordingly, FIG. 1(c) illustrates an ion implantation of a dopant material (e.g., phosphorous) into the unmasked portions of the gate conductor layer 108 corresponding to the NFET regions of the device.

In FIG. 1(d), region 110 of the gate conductor layer 108 represents the primary concentration of the heavy pre-doped material, which is generally located around the upper half to upper third of the layer. A patterned resist layer 112 defines the shape of the gate stack to be etched into the gate conductor layer 108 and gate dielectric layer. The resulting gate stack 114 is illustrated in FIG. 1(e). Prior to source/drain implantation, the gate stack 114 is subjected to a re-oxidation process in order to provide thin sidewall spacers on the vertical surface of the gate, as well as to repair any damage to the gate edge during plasma etching of the gate stack. As also indicated above, conventional gate re-oxidation involves a furnace-based process in which the wafer is subjected to a high temperature anneal about 800° C. or more in an oxygen-containing environment.

FIG. 1(f) illustrates the formation of an oxide layer 116 over the device following furnace-based oxidation. As will be noted, the conventionally formed oxide layer 116 is both grain boundary orientation dependent and dopant concentration dependent. In particular, the thickness of the oxide layer 116 is increased at locations 118 on the gate sidewalls corresponding to the location of the pre-dopant material region 110. The top-notching effect of the gate stack 114 becomes more significant with respect to dopant loss as poly gate height scale down to 50 nm and below.

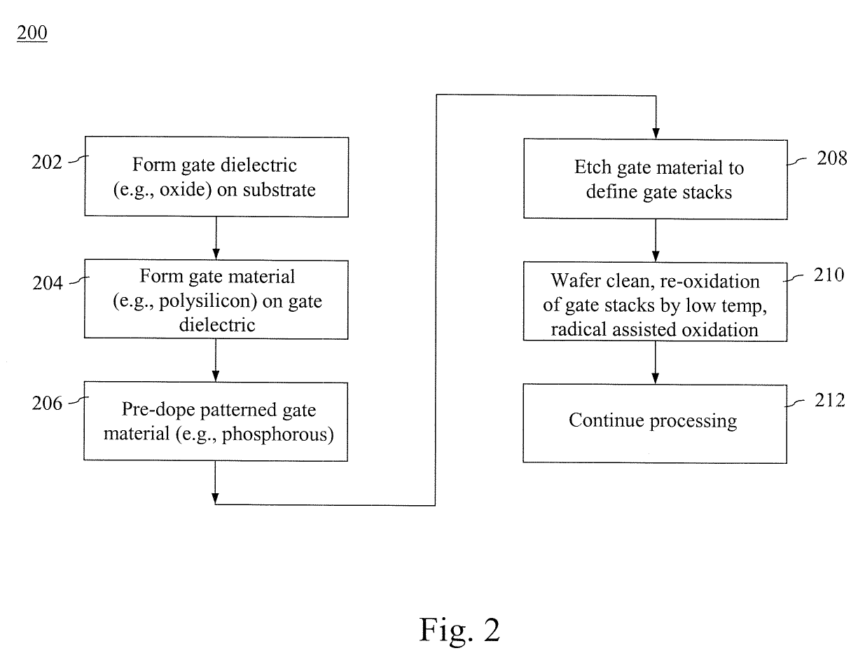

Accordingly, FIG. 2 is a process flow diagram illustrating a method for reducing top notching effects in pre-doped gate structures, in accordance with an embodiment of the invention. As shown in blocks 202 through 208, the gate dielectric deposition, gate conductor material deposition, pre-doping and gate stack etching may be performed in accordance with one or more existing process of record. However, following a wafer cleaning step upon gate stack etching, the poly gate stack is re-oxidized by a low temperature, radical-assisted process in lieu of a furnace anneal.

In an exemplary embodiment, the radical assisted oxidation may be implemented through a plasma processing system, such as the Trias™ SPA (Slot Plane Antenna) system manufactured by Tokyo Electron Limited. In such a system, a slotted dielectric member is disposed between a microwave antenna and a plasma processing chamber so as to adjust the plasma distribution within the chamber and achieve greater uniformity. Moreover, the high-density plasmas generated by such an apparatus enable damage free processes at reduced temperatures (e.g., 400° C. or less). Additional information regarding SPA processing systems may be found in U.S. Pat. No. 6,953,908 to Ishii, et al., the contents of which are incorporated herein by reference in their entirety. Following the radical assisted re-oxidation of the gate structure, additional device processing (e.g., nitride spacer formation, source/drain implantation, etc.) may continue as reflected in block 208.

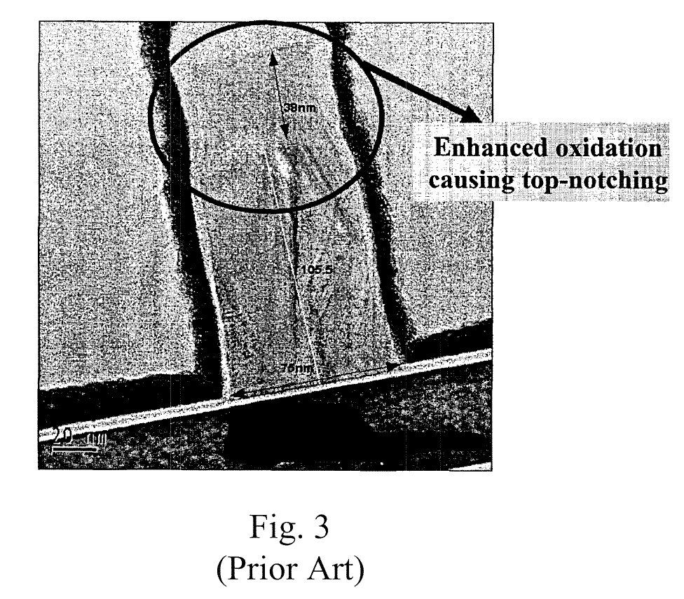

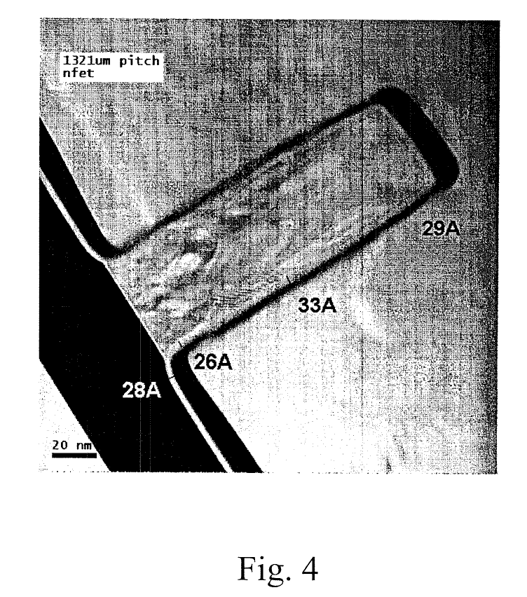

Finally, FIGS. 3 and 4 are transmission electron micrograph (TEM) photographs that illustrate a comparison between a conventional gate re-oxidation process as depicted in FIGS. 1(a) through 1(f) and a radical assisted re-oxidation process as depicted in FIG. 2. As can be seen from the TEM in FIG. 3, there is a noticeable top-notching effect due to the presence of the highly doped gate region at about the top third of the gate stack. The region of top-notching extends about 38 nm in height (thickness). Thus, for shorter gate stacks approaching 50 nm and less, the effects of top-notching on device performance become more pronounced.

In contrast, the re-oxidized gate structure of FIG. 4, using radical assisted re-oxidation, is characterized by a relatively uniform oxide thickness that is substantially grain boundary independent and independent with respect to the presence of a highly pre-doped region of the gate. More specifically, FIG. 4 illustrates a resulting oxide layer thickness of about 28 angstroms (Å) over the substrate near the corner of the gate; an oxide layer thickness of about 26 Å on the vertical sidewall near the bottom of the gate; an oxide layer thickness of about 33 Å on the vertical sidewall approximately midway up the height of the gate; and an oxide layer thickness of about 29 Å on the vertical sidewall near the top of the gate.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method for reducing top notching effects in pre-doped gate structures, the method comprising:
subjecting an etched, pre-doped gate stack structure having a height of about 50 nm or less to a re-oxidation process, the re-oxidation process comprising a radical assisted re-oxidation process implemented at a temperature of about 400° C. or less using a slot plane antenna (SPA) plasma processing system as to result in the formation of an oxide layer over vertical sidewall and horizontal top surfaces of the etched gate stack structure;
wherein the oxide layer has a substantially uniform thickness independent of grain boundary orientations of the gate stack structure and independent of the concentration and location of dopant material present therein;
wherein the gate stack structure comprises an NFET device pre-doped with phosphorus at a concentration of about 5×10¹⁵ atoms/cm ² or more.

2-5. (canceled)

6. A method of forming a gate stack structure for a semiconductor device, the method comprising:
forming a gate dielectric layer over a semiconductor substrate;
forming a polysilicon gate conductor layer over the gate dielectric layer;
subjecting unmasked regions of the gate conductor layer to an ion implantation of dopant material;
patterning and etching the gate conductor layer and gate dielectric layer so as to form a pre-doped gate stack structure; and
subjecting the gate stack structure to a re-oxidation process, the re-oxidation process comprising a radical assisted re-oxidation process implemented at a temperature of about 400° C. or less using a slot plane antenna (SPA) plasma processing system so as to result in the formation of an oxide layer over vertical sidewall and horizontal top surfaces of the etched gate stack structure;
wherein the oxide layer has a substantially uniform thickness independent of grain boundary orientations of the gate stack structure and independent of the concentration and location of dopant material present therein; and
wherein the gate stack structure comprises an NFET device pre-doped with phosphorus at a concentration of about 5×10¹⁵ atoms/cm ² or more.

7-11. (canceled)
